(19) United States
(12) Patent Application Publication
(10) Pub. No.: US 2011/0134514 A1
(43) Pub. Date: Jun. 9, 2011

(54) Flexible Substrate Having Electrical And Optical Functions

(76) Inventors: Karl S. Weibezahn, Corvallis, OR (US); Stephan R. Clark, Albany, OR (US); Scott Lerner, Corvallis, OR (US); John P. Whitlock, Corvallis, OR (US)

(21) Appl. No.: 12/631,972

(22) Filed: Dec. 7, 2009

(51) Int. Cl. G02B 5/10; H05K 1/00; G02B 5/08; B05D 5/12; C25D 7/08

(52) U.S. Cl. 359/359; 174/254; 359/883; 359/868; 427/58; 205/116

(57) ABSTRACT

A flexible substrate having electrical and optical functions. The substrate includes a planar non-conductive film. The substrate also includes a seed layer on a first region of the film for fabrication of conductive traces to couple to an electro-optical component disposed adjacent the first region. The substrate further includes a smooth optically reflective layer disposed on a second region of the film.

### BACKGROUND

Electro-optical systems, such as solar cell arrays for converting light to electricity, perform both electrical functions and optical functions. Such arrays may include, for example, electrical elements such as photovoltaic cells that convert light to electricity, and conductive traces that interconnect the cells and route the electrical current. Such arrays may also include optical features that direct and/or concentrate the light received by the array onto its photovoltaic cells in order to increase the efficiency of operation of, and thus the power generated by, the array.

There is increased interest in using solar power to reduce the use of fossil fuels for generating electricity. A reduction in the cost of such electro-optical systems can spur increased deployment and help achieve this goal.

### BRIEF DESCRIPTION OF THE DRAWINGS

FIG. 1A is a schematic cross-sectional representation of a portion of an exemplary flexible substrate having electrical and optical functions in accordance with an embodiment of the present invention.

FIG. 1B is a schematic cross-sectional representation of a portion of another exemplary flexible substrate having electrical and optical functions in accordance with an embodiment of the present invention.

FIG. 2A is a schematic plan view of one side of the flexible substrate of FIG. 1A or 1B in accordance with an embodiment of the present invention.

FIG. 2B is an enlarged view of a portion of the one side of the flexible substrate of FIG. 2A in accordance with an embodiment of the present invention.

FIG. 3 is a schematic representation of an exemplary flexible substrate configured to form a parabolic light concentrator in accordance with an embodiment of the present invention.

FIG. 4 is a flowchart of a method for fabricating the flexible electro-optical substrates of FIGS. 1A-1B in accordance with an embodiment of the present invention.

FIG. 5 is a lower-level flowchart of one method of patterning conductive traces usable with the method of FIG. 4 in accordance with an embodiment of the present invention.

FIG. 6 is a lower-level flowchart of another method of patterning conductive traces usable with the method of FIG. 4 in accordance with an embodiment of the present invention.

FIG. 7 is a schematic plan view of an exemplary electrical region of the flexible substrate of FIG. 1A, where the cross-sectional representation of FIG. 1A is taken along lines A-A′ of FIG. 7, in accordance with an embodiment of the present invention.

### DETAILED DESCRIPTION

Referring now to the drawings, there is illustrated an embodiment of a flexible substrate having electrical and optical functions which can be fabricated using roll-to-roll technology in a cost-effective, mass-produced manner.

The flexible substrate, in one embodiment, is a planar structure that has the features that provide the electrical functions, such as conductive traces, on a first region, and has the features that provide the optical functions on a second region. In some embodiments, the first region may be on a first side of the substrate, and the second region on a second side of the substrate opposite the first side. The optical features on the second region may include a uniform optically reflective layer. The substrate is usable to form an electro-optical system or device. In some embodiments, an electro-optical component such as a photovoltaic cell is disposed adjacent the first region and electrically connected to certain of the conductive traces. In some embodiments, a window formed in the substrate adjacent to the position of the electro-optical component allows light impinged on the window to pass through the second side of the substrate and onto a surface of the electro-optical component. The flexible substrate may be bent into a generally serpentine shape such that the reflective layer forms a parabolic light concentrator that focuses light impinged on the reflective layer at the location of the window. This increases the efficiency of operation of, and the power generated by, the photovoltaic cell.

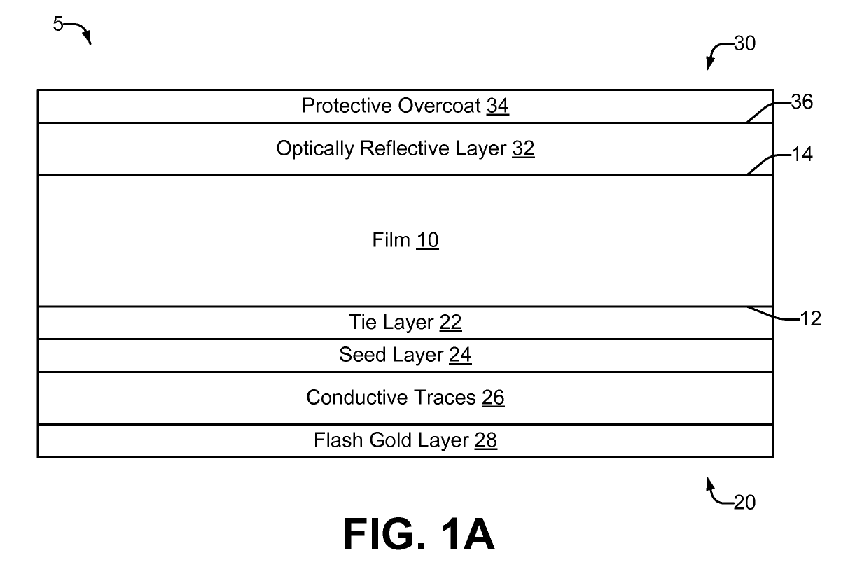

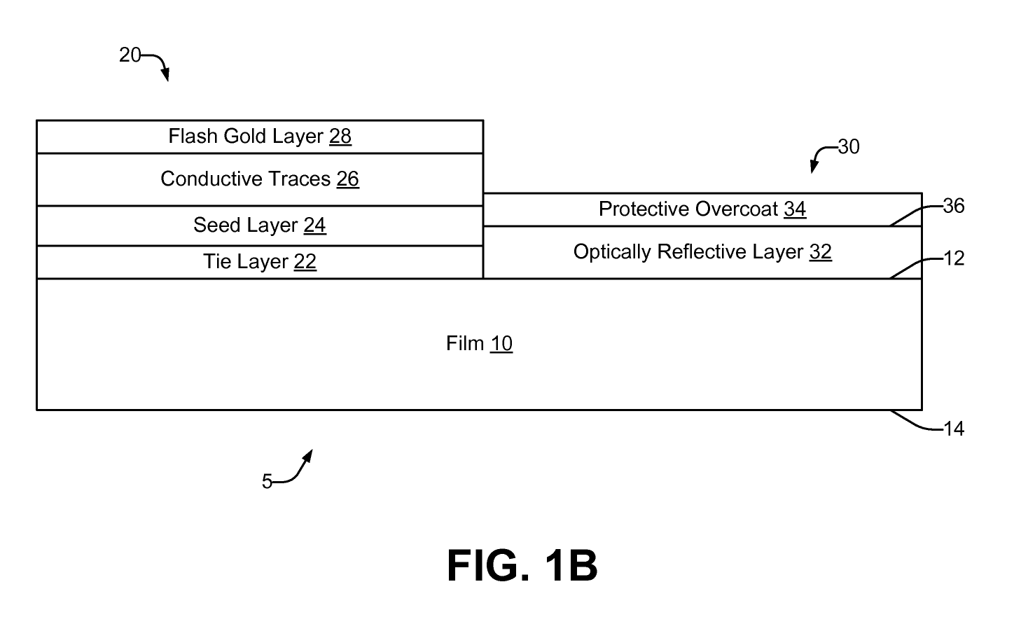

Considering now in further detail the structure of a portion of one exemplary flexible substrate having electrical and optical functions, and with reference to FIG. 1A, the substrate 5 has a non-electrically-conductive flexible film 10 as its base. The film 10 may be a substantially planar plastic film, such as polyethylene naphthalate (PEN), polyethylene terephthalate (PET), Polyimide, or other films having high biaxial stability, low coefficient of thermal expansion, and high glass transition temperature. In one embodiment, the film 10 has a uniform thickness between 3 mil (3 thousandths of an inch) and 7 mil. In another embodiment, the film 10 has a uniform thickness of about 5 mil. In one embodiment, the film 10 has a glass transition temperature greater than 120 degrees C. At least one side of the film 10 has a smooth surface finish. In one embodiment, the smooth surface finish is characterized by an average roughness of less than 10 nanometers.

The film 10 has a first side 12 that includes, or corresponds to, the first, or electrical, region 20 of the substrate 5. The film 10 also has a second side 14 that includes, or corresponds to, the second, or optical, region 30 of the substrate 5.

The electrical region 20 of the substrate 5 includes one or more layers that collectively form conductive traces patterned on the first side 12 of the film 10. In some embodiments, a tie layer 22 is disposed on the first side 12 of the film 10. In one embodiment, the tie layer 22 comprises chromium, and has a thickness of about 10 nanometers (100 angstroms). The tie layer 22 may form an improved bond between the film 10 and a seed layer 24.

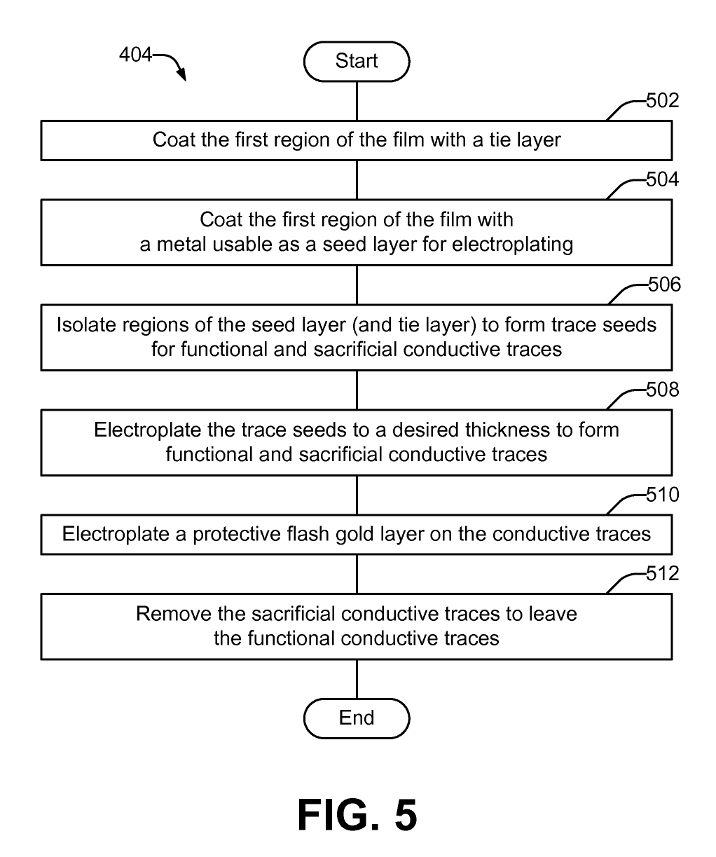

As used herein, a “seed layer” is a thin conductive layer which is capable of being built up into a thicker conductive layer through, for example, electroplating. The seed layer 24 is bonded or adhered to the first side 12 of the film 10, with or without use of tie layer 22 as an intermediary. The seed layer 24 is a metal layer, which may be copper, nickel, or another conductive metal. In one embodiment, the seed layer 24 has a thickness in the range of 50 to 100 nanometers. As will be discussed subsequently in greater detail with reference to FIGS. 5-7, at least a portion of the seed layer 24 is patterned to define the geometry of conductive traces 26 on the electrical region 20.

The patterned portion of the seed layer 24 provides a conductive base pattern upon which conductive traces 26 are built up. The thickness to which the conductive traces 26 are built up is determined according to the electrical requirements, such as the amount of current to be carried. In one embodiment, the thickness is in a range between 40 micrometers and 500 micrometers.

In some embodiments, some of the conductive traces 26 may be used to conduct thermal energy rather than electrical energy. Such traces would typically be bonded to a surface of the electro-optical component thermally in order to conduct away heat generated by the component. In alternate embodiments, the traces might be used to conduct heat to the component. The thickness to which the traces 26 are built up is determined according to the thermal requirements, such as the amount of heat to be conducted.

In some embodiments, a flash gold layer 28 may be disposed on the conductive traces 26. The gold layer 28 protects the traces from environmental factors, and in some embodiments has a thickness in the range of 50 to 100 nanometers.

The optical region 30 of the substrate includes an optically reflective layer 32 disposed on the second side 14 of the film 10. In some embodiments, the optically reflective layer 32 is disposed on substantially all of the second side 14. In other embodiments, the layer 32 is disposed on one or more selected portions or regions of the second side 14. The reflective layer 32 is typically a metal coating, such as aluminum or silver. In some embodiments, the thickness of the reflective layer 32 ranges from 100 nanometers to 1000 nanometers. In one embodiment, the reflective layer 32 is 125 nanometers in thickness. The thickness of the reflective layer may be determined based on the percentage of light of the wavelengths of interest versus thickness of the reflective material. The reflective layer 32 has a smooth, unpatterned surface finish on its outer surface 36. In one embodiment, the average roughness of the outer surface 36 is less than 10 nanometers. The optically reflective layer 32 is highly reflective. In one embodiment, the optically reflective layer 32 has a total net reflectivity greater than 90% for light wavelengths above 700 nanometers.

The reflective layer 32 may be coated or uncoated. In some embodiments, a protective overcoat 34 is applied to the reflective layer 32 to protect the metal coating, particularly in the case of aluminum, from oxidation, humidity, and other environmental factors. The overcoat 34 is optically transmissive, non-distortive, smooth, and of a thickness that minimizes or eliminates back reflection. In one embodiment, the overcoat 34 is an acrylic coating between 200 to 400 nanometers in thickness. In another embodiment, the overcoat 34 is PVDF (polyvinylidene fluoride) between 5 to 8 micrometers in thickness.

Another embodiment of substrate 5 is an unpatterned substrate that has reflective layer 32, with or without overcoat 34, applied to substantially all of the second side 14 of the film 10, and seed layer 24 (with tie layer 22, if used) applied to substantially all of the first side 12 of the film 10. Unpatterned substrate 5 can advantageously be subsequently processed to form a patterned substrate 5 in a desired configuration by patterning the seed layer 24 and building up conductive traces 36 according to the pattern.

Considering now in further detail the structure of another exemplary flexible substrate having electrical and optical functions, and with reference to FIG. 1B, one side, such as the first side 12, of film 10 includes both the electrical region 20 and the optical region 30. The regions 20,30 are typically located on different portions of the first side 12. In yet a further embodiment, an electrical region 20, an optical region 30, or both may be disposed on both the first side 12 and the second side 14 of film 10.

The thickness of the various layers illustrated in FIGS. 1A-1B is not to scale. As one example, while the thickness of electrical region 20 is illustrated as greater than that of optical region 30, the thicknesses may be equal or reversed.

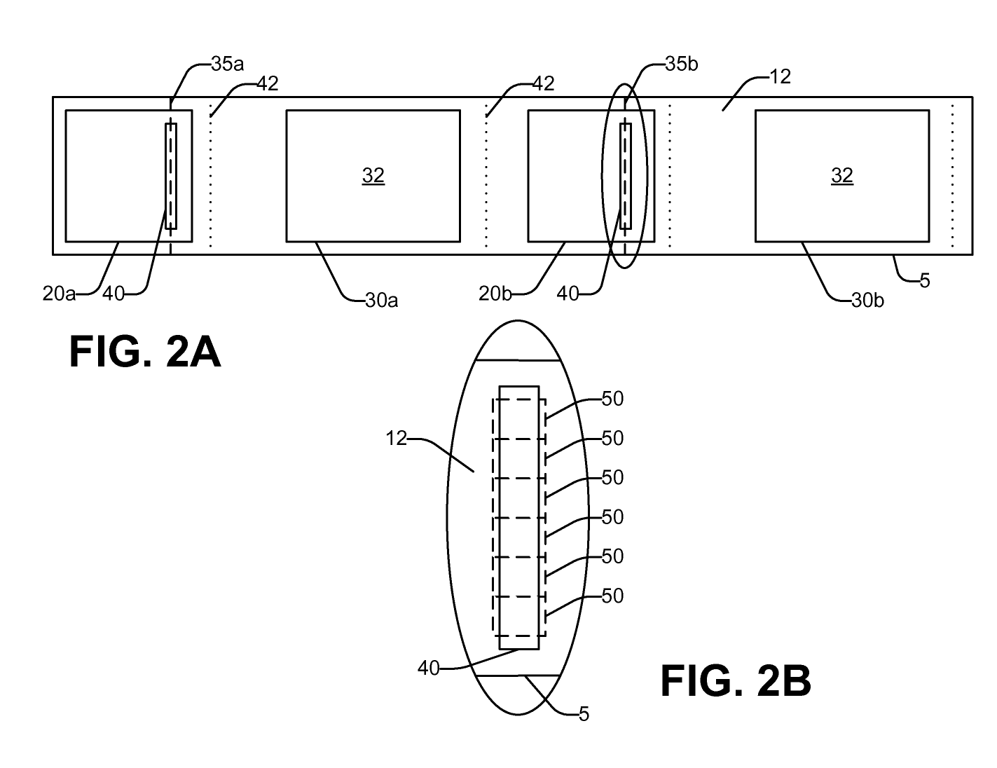

Considering now in further detail the substrate 5, and with reference to the schematic plan views of FIGS. 2A-2B, in one embodiment the substrate 5 has the form of a long strip. The flexible substrate 5 is illustrated in a flat form. A reflective layer 32 (which may in some embodiments include overcoat 34) may be disposed on one or more optical regions 30 of the substrate 5, at various positions (two such optical regions 30a,30b are illustrated in FIG. 2A, both on the same side of the substrate 5). Substrate 5 also includes one or more electrical regions 20. FIG. 2A illustrates two regions 20a,20b, disposed on the same side of the substrate 5 as the optical regions 30a,30b. In other embodiments, some or all of the electrical regions 20 may be disposed on the opposite side of the substrate 5 from the optical regions 30.

As will be discussed subsequently in greater detail, in one embodiment light that impinges an optical region 30 is concentrated and reflected onto a corresponding focal line 35 of the substrate 5. For example, optical region 30a may be associated with focal line 35a, and optical region 30b may be associated with focal line 35b.

By positioning one or more electro-optical components 50 at a focal line 35, the concentrated light will impinge the electro-optical components 50. In one embodiment, each component 50 is a photovoltaic cell which generates electrical power in response to the concentrated light impinging on the component 50. A component 50 may be positioned on the same side of the substrate 5 as the corresponding optical region 30, or on the opposite side of the substrate 5 from the corresponding optical region 30. In addition, a component 50 may be positioned on the same side of the substrate 5 as the electrical region 20 with which it is interconnected, or on the opposite side of the substrate 5 from the electrical region 20 with which it is interconnected.

In some embodiments, a window 40 formed in the substrate 5 allows light to pass through the substrate 5. In one embodiment, the window 40 is a hole or void through the substrate 5. The window 40 may be formed in a variety of sizes and shapes. In one embodiment, light impinging on the optical region 30 of the substrate 5 passes through the window 40 and impinges onto one or more electro-optical components 50 which are disposed on the opposite side of substrate 5 adjacent the window 40 at the focal line 35. In FIG. 2B, which illustrates an enlarged portion of the first side 12 of the substrate 5, six components 50, for example, are positioned adjacent the window 40 on the opposite second side 14 of the substrate 5.

In some embodiments such as, for example, ones where the electrical region 20 is on the opposite side of the substrate 5 from the side at which the component 50 is positioned adjacent, the window 40 facilitates an electrical connection between the electrical region 20 and the component 50. The window 40 may allow traces or wires from the electrical region 20 to pass through the window 40 and electrically connect to the component 50.

In some embodiments such as, for example, ones where the optical region 30, the electrical region 20, and the component 50 are on the same side of the substrate 5, there may be no window 40 adjacent the component 50. In such embodiments, neither light nor electrical connections pass through the substrate 5.

While the electrical region 20 and the optical region 30 are illustrated as having particular sizes, shapes, and positions, these are merely exemplary. Similarly, while the various regions 20,30 are illustrated as non-contiguous, some or all of the regions 20,30 may be contiguous to one another.

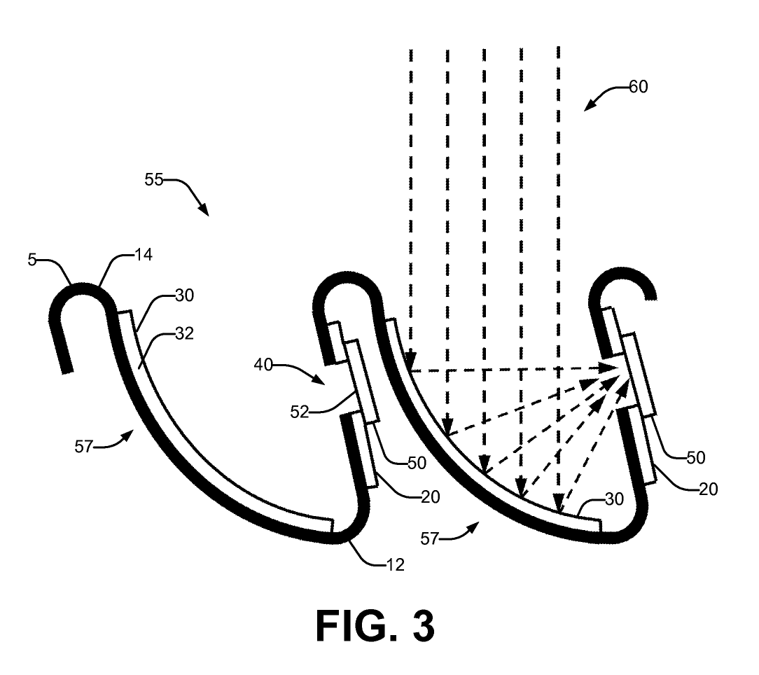

Considering now in further detail the configuration of one embodiment of the substrate 5 to form a parabolic light concentrator, and with reference to FIG. 3, the flexibility of the substrate 5 allows it to be bent into a variety of positions. In some embodiments, the substrate 5 is bent into a generally serpentine shape 55. From end-to-end, in one embodiment, the substrate 5 when bent into the generally serpentine shape 55 (as in FIG. 3) has a length equal to about one-third of the length of the substrate 5 when flat (as in FIG. 2A).

At least one portion 57 of the serpentine shape 55 forms a parabolic shape. The parabolic portion 57 of the substrate 5 is arranged with the optical region 30 and the optically reflective layer 32 on its inner, concave surface. The parabolic portion 57 forms the optically reflective layer 32 into a light concentrator, with the window 40 at the focal line of the concentrator.

In the embodiment of FIG. 3 the optically reflective layer 32 is located generally at the parabolic portion 57, on the second side 14 of the substrate 5. In other embodiments, the optically reflective layer 32 may also be located at other portions of the second side 14, or may be located on substantially the entire second side 14. In still other embodiments, the optically reflective layer 32 may be located on the first side 12.

The parabolic portion 57 is configured to direct and concentrate light 60 that impinges the portion 57, and to reflect it onto the focal line 35 (FIG. 2A). Focal line 35 typically is in the plane of surface 52 of component 50. The parabolic curvature of the parabolic portion 57 causes light 60 impinged substantially anywhere on the surface of the optical region 30 of the parabolic portion 57 to be concentrated at the focal line 35 on surface 52. The size and shape of the optically reflective parabolic portion 57, and the distance from the reflective portion 57 to the surface 52, are designed to perform this light concentration. Where component 50 is a photovoltaic cell in a solar cell array, the concentrated light impinging the surface 52 advantageously results in increased electrical power generated by the cell, thus improving the efficiency of the solar cell array in converting light to electricity. In addition, combining the electrical functions of the electrical region 20 and the optical functions of the optical region 30 into a single substrate 5 advantageously reduces the number of parts used in the solar cell array.

In embodiments such as that illustrated in FIG. 3, where the component 50 is located on the opposite side (e.g. on the first side 12) of the substrate 5 from its corresponding optical region 30 (e.g. on the second side 14), the substrate 5 includes a window 40 through which the light 60 impinges on the component 50 disposed adjacent the window 40. The window 40 allows light reflected by the reflective layer 32 to pass through the substrate 5 and impinge on the surface 52 of the component 50. The size, shape and position of the window 40 are designed, in conjunction with the size and shape of the parabolic portion 57, so as to concentrate the light 60 at the focal line 35 on the surface 52 of the component 50.

In some embodiments, one or more lines 42 (FIG. 2A, illustrated as dashed lines) may be scored across a width of, and partway through, the substrate 5 to allow the substrate 5 to bend more easily at or near the lines 42. The lines 42 may be formed at or near the sharper bends in the serpentine shape 55 to reduce spring action of the substrate and thus retain the generally serpentine shape 55.

In some embodiments, a mechanical frame, guide, or similar component (not shown) maintains the generally serpentine shape 55 of the substrate 5. More particularly, the frame or guide maintains the parabolic shape of each parabolic portion 57 and its position relative to its corresponding component (or components) 50. The geometric relationship between the components 50, as mounted on the substrate 5, and the parabolic portion 57, are further maintained since both the electrical and the optical functions are provided on the same, single substrate 5. In some embodiments, the frame or guide does not constrain movement of the substrate 5 in regions of the serpentine shape 55 other than in the region or regions of the parabolic portion 57.

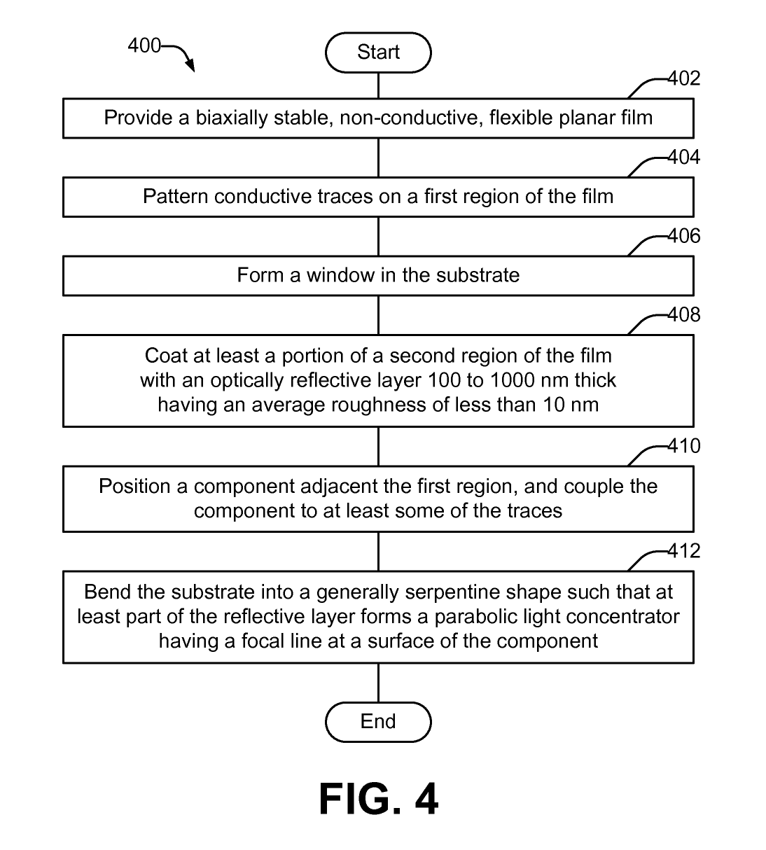

Considering now one embodiment of a method 400 of fabricating a flexible electro-optical substrate, and with reference to FIG. 4, at 402 a biaxially stable, non-conductive, flexible planar film is provided. In one embodiment, the film may be the film 10 of FIGS. 1A-1B. The method 400 may be used to produce the substrate 5 of FIGS. 1A-1B, and the method 400 is described below with reference to the substrate 5.

At 404, conductive traces 26 are patterned on a first region of the film 10, which corresponds to an electrical region 20 of the substrate. In one embodiment at least some of the traces 26 are electrically conductive. Some others of the traces 26 may be thermally conductive. Two embodiments of patterning the conductive traces 26 are described subsequently in greater detail with reference to FIGS. 5-7.

At 406, in some embodiments, a window 40 is formed in the substrate 5. In one embodiment, the window 40 is an opening excised through the substrate 5. The excising may be performed by laser ablation or other techniques. In another embodiment, the film 10 is highly light-transmissive, and the window 40 may be formed by preventing the film 10 in the area of the window 40 from being covered with other layers of the electrical region 20 and the optical region 30. The window 40 may alternatively be formed by removing any layers of the electrical region 20 and optical region 30 in the area of the window 40, or by other techniques. In embodiments where the film 10 is not removed in the area of the window 40, light can pass through the highly light-transmissive film 10 and impinge the component 50 with minimal attenuation. In one embodiment, the window forming 406 is performed after the patterning 404. In another embodiment, the window forming 406 is performed as part of the patterning 404. In other embodiments, the window forming 406 may be performed at other times. The windows 40 are typically located such that circuit traces 26 do not fall within the region of any window 40.

At 408, at least a portion of a second region of the film 10, which corresponds to an optical region 30 of the substrate 5, is coated with an optically reflective layer 32. The reflective layer 32 is typically a metal coating, such as aluminum or silver. In one embodiment, the layer 32 has a smooth, unpatterned surface finish on its outer surface 36. In one embodiment, the layer 32 is 100 to 1000 nanometers thick. In one embodiment, the layer 32 has an average surface roughness of less than 10 nanometers. In one embodiment, the optically reflective layer 32 has a total net reflectivity greater than 90% for light wavelengths above 700 nanometers. The layer 32 may be formed by physical vapor deposition, chemical vapor deposition, or other thin film deposition techniques, and could be deposited by sputtering or evaporation. In some embodiments, coating 408 the optically reflective layer 32 may include providing a protective overcoat 34 on top of the metal.

In some embodiments, the coating 408 of the optically reflective layer 32 is performed after the patterning 404 of the conductive traces 26 is complete. In other embodiments, the coating 408 of the optical layer 32 is performed before the patterning 404 of the conductive traces 26 has been fully completed. In these latter embodiments, where some or all of the patterning 404 is performed after the optically reflective layer 32 has been applied to the optical region 30 of the film 10, a protective film (not shown) may be temporarily applied over the outer surface of the optical region 30. This protective film may then be removed or peeled off after the patterning 404 of the electrical region 20 has been completed.

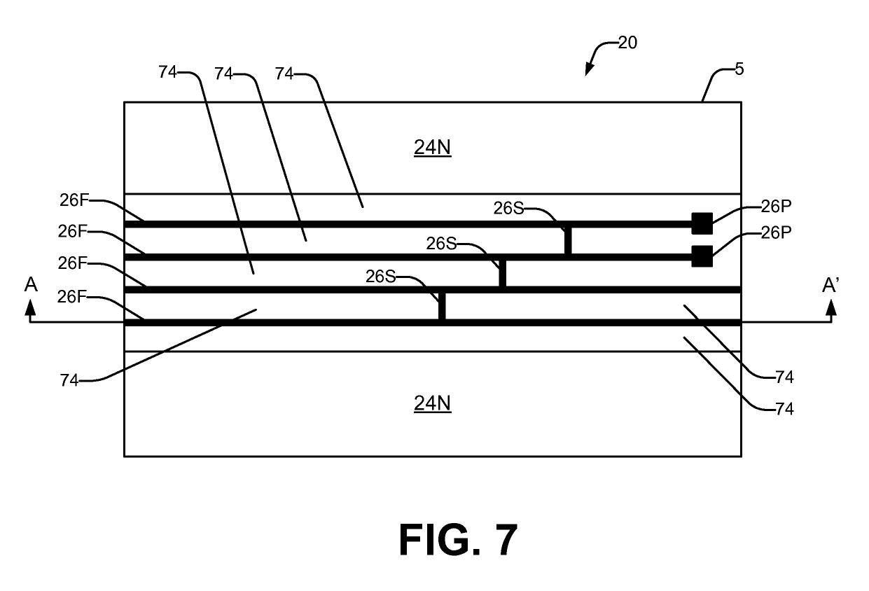

At 410, an electro-optical component 50 is positioned adjacent the first region 20, and coupled to at least some of the conductive traces 26. The electro-optical component 50 may be any kind of electrical device that has an optical function. In some embodiments, leads or pads (not shown) on the component 50 may be electrically coupled, directly or indirectly, to contact pads 26P (FIG. 7) that are formed as part of certain ones of the conductive traces 26. In various embodiments, the electrical coupling may include bonding the component 50 to the traces 26 via wire bonding and/or laser bonding. In some embodiments, the component 50 may be thermally coupled to certain ones of the conductive traces 26. Thermal coupling may involve making physical contact between the body of the component 50 and the conductive traces 26. In some embodiments, the component 50 is also physically mounted to the electrical region 20 of the substrate 5.

In another embodiment, the electro-optical component 50 may be positioned adjacent the location of a window 40, but on the opposite side of the substrate 5 from the electrical region 20. In such an embodiment, the window 40 provides access to the component 50 for electrical connections to the conductive traces of the electrical region 20.

At 412, the substrate 5 is bent into a generally serpentine shape 55 such that at least part of the reflective layer 32, corresponding to the parabolic portion 57, forms a light concentrator having a focal line 35 at a surface 52 of the component 50. In some embodiments, the bending 412 includes first scoring at least one line or trench 42 across a width of, and partway through, the substrate 5. The line or trench 42 helps the substrate 5 to retain the generally serpentine shape 55 by providing a natural bend or crease point and reducing the tendency of the substrate 5 to spring back into a flat position. In one embodiment, the lines 42 may formed by ablating the substrate 5 to about one-half its thickness. The ablation may be done in the either or both sides of substrate 5.

In some embodiments, the flexible film 10 can be provided as a web on a supply roll (not shown), and many of the steps of the method 400 can be performed using continuous roll-to-roll manufacturing techniques. In one embodiment, steps 404 through 410, and scoring the line or trench 42 of step 412, can be performed using the roll-to-roll technique. This results in a finished web that has multiple substrates 5 replicated in the cross-web and down-web directions along the web. The individual substrates 5 can then be cut from the finished web and subsequently bent into the desired serpentine shape 55. This manufacturing technique results in a fast, low-cost fabrication process with high yields.

Considering now in further detail one embodiment of patterning 404 the conductive traces 26 on the first region of the film 10, and with reference to FIGS. 5 and 7, the first region is coated with a tie layer 22 at 502. Certain metals used for the seed layer 24 may not adhere well to certain compositions of film 10. For example, copper may not adhere well to PEN.

In such situations, to improve the adherence, an intermediary material may be used as a tie layer 22. In one embodiment, the tie layer 22 is chromium and the seed layer 24 is copper. The tie layer 22 may be formed by physical vapor deposition, chemical vapor deposition, or other thin film deposition techniques, and could be deposited by sputtering or evaporation. Alternatively, the surface of the first region may be prepared by, for example, an acid etch to make the seed layer 24 better adhere to the PEN. In other embodiments in which the metal used for the seed layer 24 adheres well to the composition of the film, the tie layer 22 is omitted.

At 504, the first region of the film 10 is coated with a metal usable as a seed layer 24 for electroplating purposes. The seed layer 24 may be copper, nickel, or another conductive metal. The seed layer 24 may be bonded or adhered to the film with or without use of an intermediary tie layer 22. The seed layer 24 may be formed by physical vapor deposition, chemical vapor deposition, or other thin film deposition techniques, and could be deposited by sputtering or evaporation. In one embodiment, the seed layer 24 is a bulk metal coating, which in some embodiments may be coated on substantially all of one side of the film 10.

Additionally referring now to FIG. 7, at 506, regions of the seed layer 24 (and tie layer 22, if present) are isolated from the remainder of the seed layer 24 (and tie layer 22, if present), to form trace seeds for functional conductive traces 26F and sacrificial conductive traces 26S. The trace seeds are the isolated regions of the seed layer 24 that underlie, and have the same geometry on the first side 12 of the film 10 as, the traces 26F,26S. As such, they provide a conductive base pattern for the traces. The trace seeds are subsequently built up to the thickness desired for the functional conductive traces 26F. Considering the cross-sectional view of the exemplary substrate 5 in FIG. 1A, taken along line A-A′ and through one of the traces 26F of FIG. 7, the portion of seed layer 24 underlying conductive trace 26F is the trace seed for conductive trace 26F.

The isolation of the regions of the seed layer 24 that correspond to the functional traces 26F and sacrificial traces 26S includes the removal of the bulk metal coating (including any underlying tie layer 22) in areas 74 of the first side that surround the traces 26F,26S. As a result, there is no conductive connection between the traces 26F,26S and any remaining non-trace portions 24N of the seed layer where the bulk metal is not removed.

In one embodiment, the bulk metal coating removed from areas 74 to isolate the traces 26F,26S is removed via laser ablation. In another embodiment, the bulk metal coating is removed via photolithographic techniques. In one embodiment, the portions of the bulk metal coating corresponding to the non-trace portions 24N of the seed layer 24 is not removed.

At 508, the trace seeds are electroplated to a desired thickness to form the functional 26F and sacrificial 26S conductive traces. The functional traces 26F include the electrically and/or thermally conductive traces that couple the electro-optical components 50 to the substrate 5. The sacrificial traces 26S are temporary bridge traces that electrically interconnect the functional traces 26F. The sacrificial traces 26S form a current path for electrolytic plating of the functional traces 26F. In one embodiment, the metal plated onto the trace seeds to form the traces 26F,26S is the same as, or compatible with, the metal or metal alloy used to form the seed layer. Thus, as a non-limiting example, the traces can be built up with copper, nickel, a metal alloy, etc. of desired thickness. The thickness to which the conductive traces 26F,26S are built up is determined according to the electrical requirements, such as the amount of current to be carried. In one embodiment, the thickness is in a range between 40 micrometers and 500 micrometers.

At 510, in some embodiments, a protective flash gold layer 28 is electroplated on the conductive traces. In one embodiment, the gold layer is 50 to 100 nanometers in thickness.

At 512, the sacrificial electrical traces 26S are removed to leave the functional electrical traces 26F. In one embodiment, the traces 26S are removed via laser ablation. The traces may be removed after all the electroplating operations have been performed.

The process 404 described with reference to FIG. 5 fabricates a single conductive layer. However, other techniques can be used to fabricate multiple conductive layers on the electrical region 20 of substrate 5.

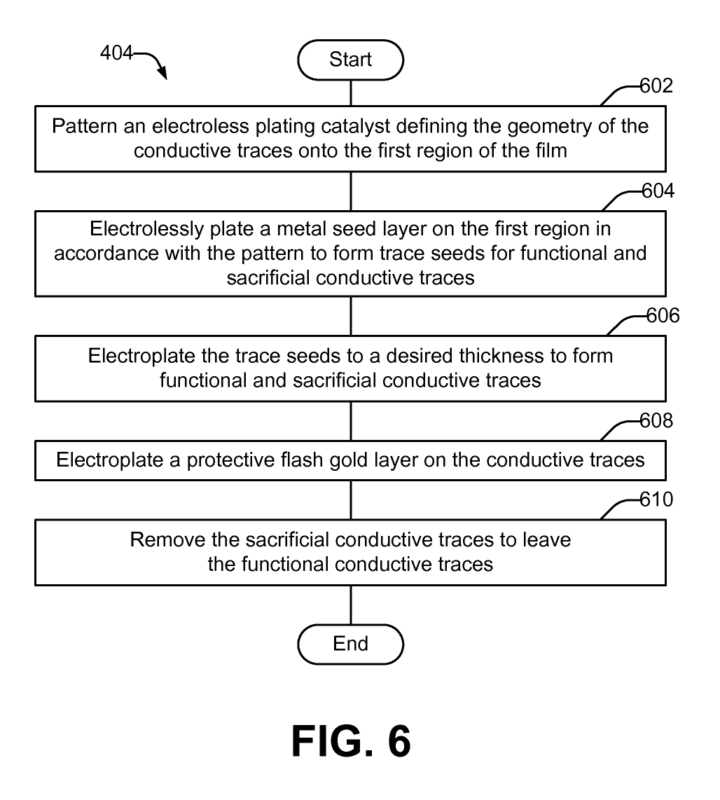

Considering now in further detail another embodiment of patterning 404 the conductive traces on the electrical region of the film, and with reference to FIG. 6, at 602, an electroless plating catalyst defining the geometry of the conductive traces is patterned onto the first region of the film 10. The pattern corresponds to the conductive traces desired on the first region. In one embodiment, the plating catalyst can be Cataposit 44 Catalyst as available from Rohm & Haas Co., Philadelphia, Pa., USA. In one embodiment, the plating catalyst is applied as a layer less than one-hundred nanometers in thickness. Other thicknesses can also be used. In one embodiment, the plating catalyst is deposited on the first region via inkjet printing in the desired pattern.

At 604, a metal seed layer 24 is electrolessly plated on the first region in accordance with the pattern defined by the electroless plating catalyst. The seed layer 24 forms trace seeds for functional 26F and sacrificial 26S conductive traces. The seed layer 24 has a thickness sufficient to provide a conductive path for subsequent electroplating. In one embodiment, the seed layer 24 thickness is in the range of one to two micrometers.

At 606, the trace seeds are electroplated to a desired thickness to form functional 26F and sacrificial 26S conductive traces, in a manner similar to step 508. At 608, in some embodiments, a protective flash gold layer 28 is electroplated on the conductive traces, in a manner similar to step 510. At 610, the sacrificial conductive traces 26S are removed to leave the functional conductive traces 26F, in a manner similar to step 512.

The process 404 described with reference to FIG. 6 fabricates a single conductive layer. However, other techniques can be used to fabricate multiple conductive layers on the electrical region 20 of substrate 5.

Embodiments of the flexible substrate of the present disclosure are not limited to use with photovoltaic cell electro-optical components, solar cell arrays, or light-receiving components. For instance, the substrate may alternatively be used in conjunction with light-generating electro-optical components, such as LEDs, projector bulbs, and the like. In embodiments of such applications, the optically reflective layer 32 on the optical region 30 of the substrate 5 may project and/or direct light that is generated by the component 50 and projected from the component 50 onto the optically reflective layer 32 in a direction opposite to that of the light 60 (FIG. 3).

From the foregoing it will be appreciated that the flexible substrate and methods that are provided by the present disclosure represent a significant advance in the art. Although several specific embodiments have been described and illustrated, the disclosure is not limited to the specific methods, forms, or arrangements of parts so described and illustrated. This description should be understood to include all novel and non-obvious combinations of elements described herein, and claims may be presented in this or a later application to any novel and non-obvious combination of these elements. The foregoing embodiments are illustrative, and no single feature or element is essential to all possible combinations that may be claimed in this or a later application. Unless otherwise specified, steps of a method claim need not be performed in the order specified. Terms of orientation and relative position (such as “top,” “bottom,” “side,” and the like) used herein are not intended to require a particular orientation and are used only for convenience of illustration and description. The disclosure is not limited to the above-described implementations, but instead is defined by the appended claims in light of their full scope of equivalents. Where the claims recite “a” or “a first” element of the equivalent thereof, such claims should be understood to include incorporation of one or more such elements, neither requiring nor excluding two or more such elements.

What is claimed is:

1. A flexible substrate having electrical and optical functions, comprising:
a planar non-conductive film;
a seed layer on a first region of the film for fabrication of conductive traces to couple to an electro-optical component disposed adjacent the first region; and
a smooth optically reflective layer disposed on a second region of the film.

2. The substrate of claim 1, comprising:
a window in the substrate, adjacent the component, that allows light reflected by the reflective layer to pass through the substrate and impinge on a surface of the component.

3. The substrate of claim 1, wherein a portion of the substrate is arranged in a parabolic shape to form a light concentrator having a focal line at a surface of the component.

4. The substrate of claim 2, wherein the component comprises a plurality of components and the window comprises a corresponding plurality of windows, and wherein the substrate is arranged in a serpentine shape having parabolic portions each forming a light concentrator, with each window at a focal line of each concentrator.

5. The substrate of claim 1, wherein the optically reflective layer has a total net reflectivity greater than 90% for light wavelengths above 700 nm.

6. The substrate of claim 1, wherein the optically reflective layer has an average roughness of less than 10 nanometers.

7. The substrate of claim 1, wherein the optically reflective layer has a thickness between 100 and 1000 nanometers.

8. The substrate of claim 1, wherein the first region is on a first side of the film, and wherein the second region is on a second, opposite side of the film.

9. The substrate of claim 1, wherein the conductive traces comprise electrically conductive traces and thermally conductive traces different from the electrically conductive traces.

10. The substrate of claim 1, wherein the seed layer is on substantially all of a first side of the film, and wherein the reflective layer is on substantially all of a second, opposite side of the film.

11. A method of fabricating a flexible electro-optical substrate, comprising:
providing a non-conductive planar film;
patterning, on a first region of the film, conductive traces for bonding to an electro-optical component disposed adjacent the first region; and
disposing, on a second region of the film, an optically reflective layer having a thickness between 100 and 1000 nanometers and an average roughness of less than 10 nanometers.

12. The method of claim 11, wherein the first region is on a first side of the film and the second region is on a second, opposite side of the film, the method further comprising:
forming a window in the substrate, adjacent the component, that allows light reflected by the reflective layer to pass through the substrate and impinge on a surface of the component.

13. The method of claim 11, comprising:
bending the substrate to form the reflective layer into a parabolic light concentrator having a focal line at the electro-optical component.

14. The method of claim 13, wherein the substrate is bent in a generally serpentine shape, the method comprising:
scoring a line across a width of, and partway through, the substrate to retain the generally serpentine shape.

15. The method of claim 11, wherein the patterning includes:
coating the first region with a bulk metal coating seed layer;
isolating regions of the seed layer to form trace seeds;
electrolytically plating the trace seeds to form functional and sacrificial conductive traces; and
removing the sacrificial traces.

16. The method of claim 11, wherein the patterning includes:
depositing at desired locations on the first region an electroless plating catalyst to form trace seeds at the desired locations;
electrolytically plating the trace seeds to form functional and sacrificial conductive traces; and
removing the sacrificial traces.

17. The method of claim 12, wherein forming the window in the substrate includes excising an opening through the substrate.

18. A substrate having electrical and optical functions, comprising:
a flexible film;
an electrical region of the film having electrically conductive traces for bonding to an electro-optical component adjacent the electrical region;
an optical region of the film having a smooth optically reflective layer; and
wherein the substrate is flexed to form the reflective layer into a parabolic light concentrator that reflects light impinged onto the concentrator onto a surface of the component.

19. The substrate of claim 18, wherein the optically reflective layer has a total net reflectivity greater than 90% for light wavelengths above 700 nm.

20. The substrate of claim 18, wherein the optically reflective layer has an average roughness of less than 10 nanometers.
